(19) United States
(12) Patent Application Publication
(10) Pub. No.: US 2025/0279232 A1
(43) Pub. Date: Sep. 4, 2025

(54) CURRENT INTRODUCTION LINE AND SUPERCONDUCTING MAGNET DEVICE

(71) Applicant: SUMITOMO HEAVY INDUSTRIES, LTD., Tokyo (JP)

(72) Inventor: Kenta DEMURA, Yokosuka-shi (JP)

(21) Appl. No.: 19/211,148

(22) Filed: May 17, 2025

Related U.S. Application Data
(63) Continuation of application No. PCT/JP2023/036219, filed on Oct. 4, 2023.

(30) Foreign Application Priority Data
Dec. 21, 2022 (JP) 2022-204676

(51) Int. Cl. H01F 6/06; H01F 6/04

(52) U.S. Cl. CPC H01F 6/065; H01F 6/04

(57) ABSTRACT

A current introduction line for introducing a current into a superconducting coil in a vacuum vessel, includes: a vacuum feedthrough; a busbar that is disposed in the vacuum vessel and is electrically connected to the superconducting coil; and a rigid conductor that is fixed to the vacuum vessel so as to be thermally coupled to the vacuum vessel and to be electrically insulated from the vacuum vessel, and electrically connects the vacuum feedthrough to the busbar.

### CROSS-REFERENCE TO RELATED APPLICATIONS

This is a bypass continuation of International PCT Application No. PCT/JP2023/036219, filed on Oct. 4, 2023, which claims priority to Japanese Patent Application No. 2022-204676, filed on Dec. 21, 2022, which are incorporated by reference herein in their entirety.

### BACKGROUND

### Technical Field

Certain embodiments of the present invention relate to a current introduction line and a superconducting magnet device.

### Description of Related Art

In general, a superconducting magnet device includes a superconducting coil and a vacuum vessel that accommodates the superconducting coil in a state of being cooled to a cryogenic temperature. In order to supply power to the superconducting coil from the outside, a coil electrode is provided outside the vacuum vessel. The coil electrode is cooled by thermal conduction from the superconducting coil. Therefore, moisture in the air surrounding the vacuum vessel may adhere to or freeze on the coil electrode. In the related art, in order to prevent such condensation, it is known to blow heated air onto the coil electrode to heat the coil electrode.

### SUMMARY

According to an embodiment of the present invention, there is provided a current introduction line for introducing a current into a superconducting coil in a vacuum vessel. The current introduction line includes: a vacuum feedthrough; a busbar that is disposed in the vacuum vessel and is electrically connected to the superconducting coil; and a rigid conductor that is fixed to the vacuum vessel so as to be thermally coupled to the vacuum vessel and to be electrically insulated from the vacuum vessel, and electrically connects the vacuum feedthrough to the busbar.

According to another embodiment of the present invention, there is provided a superconducting magnet device including a vacuum vessel, a superconducting coil disposed in the vacuum vessel, and a current introduction line for introducing a current into the superconducting coil. The current introduction line includes a vacuum feedthrough, a busbar that is disposed in the vacuum vessel and is electrically connected to the superconducting coil, and a rigid conductor that is fixed to the vacuum vessel so as to be thermally coupled to the vacuum vessel and to be electrically insulated from the vacuum vessel, and electrically connects the vacuum feedthrough to the busbar.

### BRIEF DESCRIPTION OF THE DRAWINGS

FIG. 1 is a diagram schematically showing a superconducting magnet device according to an embodiment.

FIG. 2 is a perspective view schematically showing a current introduction line according to the embodiment.

FIG. 3 is a side view schematically showing another example of the current introduction line according to the embodiment.

### DETAILED DESCRIPTION

It is desirable to suppress condensation on a current introduction line of a superconducting magnet device with a simple configuration.

Hereinafter, an embodiment for carrying out the present invention will be described in detail with reference to the drawings. In the description and drawings, identical or equivalent components, members, and processing are denoted by the same reference numerals, and overlapping description is omitted as appropriate. The scale or shape of each part that is shown in the drawings is conveniently set for ease of description and is not limitedly interpreted unless otherwise specified. The embodiment is merely an example and does not limit the scope of the present invention in any way. All characteristics and combinations to be described in the embodiment are not necessarily essential to the invention.

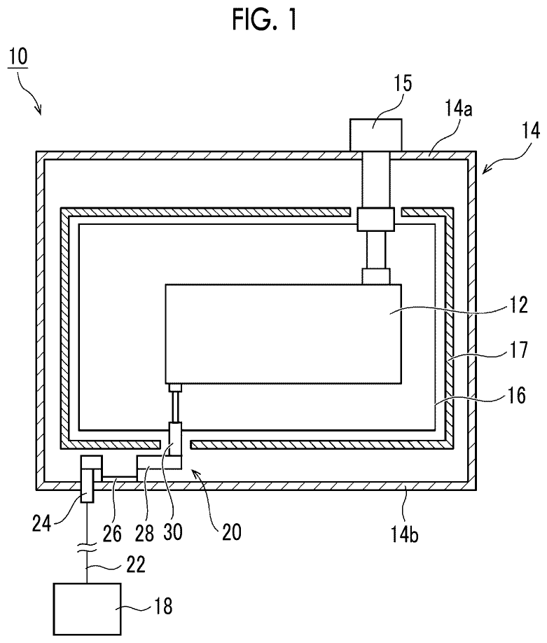

FIG. 1 is a diagram schematically showing a superconducting magnet device 10 according to an embodiment. The superconducting magnet device 10 can be mounted on a high-magnetic field utilization device as a magnetic field source of, for example, a single crystal pulling device, a nuclear magnetic resonance (NMR) system, a magnetic resonance imaging (MRI) system, an accelerator such as a cyclotron, a high energy physics system such as a nuclear fusion system, or other high-magnetic field utilization devices (not shown) and can generate a high magnetic field required for the device.

The superconducting magnet device 10 includes a superconducting coil 12, a vacuum vessel 14, a heat shield 16, and a current introduction line 20.

The superconducting coil 12 is disposed in the vacuum vessel 14, and is configured to generate a strong magnetic field by being energized in a state of being cooled to a cryogenic temperature equal to or lower than a superconducting transition temperature. The superconducting coil 12 may be a known superconducting coil (for example, a so-called low-temperature superconducting coil).

The superconducting coil 12 is connected to an external power source 18 disposed outside the vacuum vessel 14 by a current introduction line 20. An excitation current is supplied from the external power source 18 to the superconducting coil 12 through the current introduction line 20.

The superconducting coil 12 is thermally coupled to a cryocooler 15, for example, a two-stage Gifford-McMahon (GM) cryocooler or other types of cryocoolers installed in the vacuum vessel 14, and is used in a state of being cooled to a cryogenic temperature equal to or lower than a superconducting transition temperature. In this embodiment, the superconducting magnet device 10 is configured as a so-called conduction-cooled type in which the superconducting coil 12 is directly cooled by the cryocooler 15, instead of an immersion-cooled type in which the superconducting coil 12 is immersed in a cryogenic liquid refrigerant such as liquid helium. The superconducting magnet device 10 may be of an immersion-cooled type.

The vacuum vessel 14 is an adiabatic vacuum vessel that provides a cryogenic vacuum environment suitable for bringing the superconducting coil 12 into a superconducting state, and is also called a cryostat. Typically, the vacuum vessel 14 has a columnar shape or a cylindrical shape with a hollow portion at a central portion thereof. Therefore, the vacuum vessel 14 includes a substantially flat circular or annular top plate 14a and bottom plate 14b, and a cylindrical side wall (cylindrical outer peripheral wall, or coaxially disposed cylindrical outer peripheral wall and inner peripheral wall) connecting the top plate 14a and the bottom plate 14b. The cryocooler 15 may be installed on the top plate 14a of the vacuum vessel 14. The vacuum vessel 14 is formed of, for example, a metal material such as stainless steel or other suitable high-strength materials to withstand an ambient pressure (for example, atmospheric pressure).

The heat shield 16 is disposed to surround the superconducting coil 12 within the vacuum vessel 14. The heat shield 16 is formed of, for example, a metal material such as copper or other materials having high thermal conductivity. The heat shield 16 may be cooled by a first-stage cooling stage of the two-stage cryocooler 15 that cools the superconducting coil 12, or by a single-stage cryocooler separate from the two-stage cryocooler. During an operation of the superconducting magnet device 10, the heat shield 16 is cooled to a first cooling temperature, for example, 30 K to 50 K, and the superconducting coil 12 is cooled to a second cooling temperature lower than the first cooling temperature, for example, 3 K to 20 K (for example, about 4 K). The heat shield 16 can thermally protect a low-temperature section such as the superconducting coil 12, which is disposed inside the heat shield 16 and is cooled to a lower temperature than the heat shield 16, from radiant heat from the vacuum vessel 14.

The current introduction line 20 for introducing a current into the superconducting coil 12 includes an external wire 22, a vacuum feedthrough 24, a rigid conductor 26, a busbar 28, and a current lead portion 30, and forms a current path from the external power source 18 to the superconducting coil 12. For simplicity, only one current introduction line 20 is shown in FIG. 1. However, in general, a plurality of the current introduction lines 20 may be provided in the superconducting magnet device 10, and for example, one current introduction line 20 on a positive electrode side and one current introduction line 20 on a negative electrode side may be provided.

The external wire 22 disposed outside the vacuum vessel 14 connects the external power source 18 to the vacuum feedthrough 24 provided in a wall portion of the vacuum vessel 14. The external wire 22 may be a suitable power supply cable.

The vacuum feedthrough 24 is a hermetically sealed terminal for introducing a current into the vacuum vessel 14, and connects the external wire 22 to internal wires (that is, the rigid conductor 26, the busbar 28, and the current lead portion 30) inside the vacuum vessel 14. The current introduction line 20 can penetrate the wall portion of the vacuum vessel 14 while maintaining airtightness of the vacuum vessel 14 using the vacuum feedthrough 24. The vacuum feedthrough 24 is exposed to an ambient environment (for example, room temperature and atmospheric pressure environment) of the vacuum vessel 14, and thus is at an ambient temperature (for example, room temperature).

In the embodiment, as shown, the vacuum feedthrough 24 is installed on the bottom plate 14b of the vacuum vessel 14, and the current introduction line 20 is disposed at an outer peripheral portion of the vacuum vessel 14 on a lower side. This disposition is advantageous from the viewpoint of workability. Depending on the application of the superconducting magnet device 10, the vacuum vessel 14 is often considerably larger than a worker (for example, several meters or more in diameter). When the vacuum feedthrough 24 is provided at the outer peripheral portion of the vacuum vessel 14, it is easy for the worker to access the current introduction line 20 from around the superconducting magnet device 10. The vacuum feedthrough 24 may be installed on an upper surface of the vacuum vessel 14, and the current introduction line 20 may be disposed at the outer peripheral portion of the vacuum vessel 14 on an upper side. Alternatively, the vacuum feedthrough 24 and the current introduction line 20 may be provided at other portions of the vacuum vessel 14.

The rigid conductor 26 and the busbar 28 are disposed outside the heat shield 16 in the vacuum vessel 14, and connect the vacuum feedthrough 24 to the current lead portion 30. The vacuum feedthrough 24, the rigid conductor 26, and the busbar 28 are formed of a conductive material, for example, a metal material having excellent conductivity typified by pure copper such as oxygen-free copper, and serve as the current path to the superconducting coil 12.

Although details will be described later, the rigid conductor 26 is fixed to the vacuum vessel 14 so as to be thermally coupled to the vacuum vessel 14 and to be electrically insulated from the vacuum vessel 14, and electrically connects the vacuum feedthrough 24 to the busbar 28. The busbar 28 is electrically connected to the superconducting coil 12 through the current lead portion 30.

The busbar 28 may be thermally coupled to the heat shield 16 in a state of being electrically insulated from the heat shield 16. An end portion of the busbar 28 on a side opposite to the rigid conductor 26 may be fixed to the heat shield 16 or may be connected to the heat shield 16 via an appropriate heat transfer member to be cooled to the first cooling temperature in the same manner as the heat shield 16. Therefore, the current introduction line 20 can have a temperature distribution in which the temperature gradually decreases from the vacuum feedthrough 24 to the rigid conductor 26 and the busbar 28.

The rigid conductor 26 and the busbar 28 may be disposed outside a thermal insulation layer 17. The thermal insulation layer 17 may be provided between the vacuum vessel 14 and the heat shield 16 in order to protect the heat shield 16 from radiant heat emitted from the vacuum vessel 14. The thermal insulation layer 17 may be, for example, a multilayer insulation (MLI), and may be disposed to surround the heat shield 16.

In this embodiment, the busbar 28 is a rigid conductor separate from the rigid conductor 26. However, in a certain embodiment, the rigid conductor 26 and the busbar 28 may be configured as a single conductor member.

The current lead portion 30 is disposed inside the heat shield 16, and connects the busbar 28 to the superconducting coil 12. The current lead portion 30 may extend in a different direction within the vacuum vessel 14 than the busbar 28. In the shown example, the current lead portion 30 may extend from the end portion of the busbar 28 to the superconducting coil 12 in a longitudinal direction (vertical direction). The current lead portion 30 may include terminal portions at both ends respectively connected to the busbar 28 and the superconducting coil 12, and a superconducting current lead connecting the terminal portions. The superconducting current lead may have, for example, a rod shape such as a columnar shape, and may be formed of a copper oxide superconductor or other high-temperature superconducting materials. Alternatively, the superconducting current lead may be formed of a low-temperature superconducting material represented by NbTi.

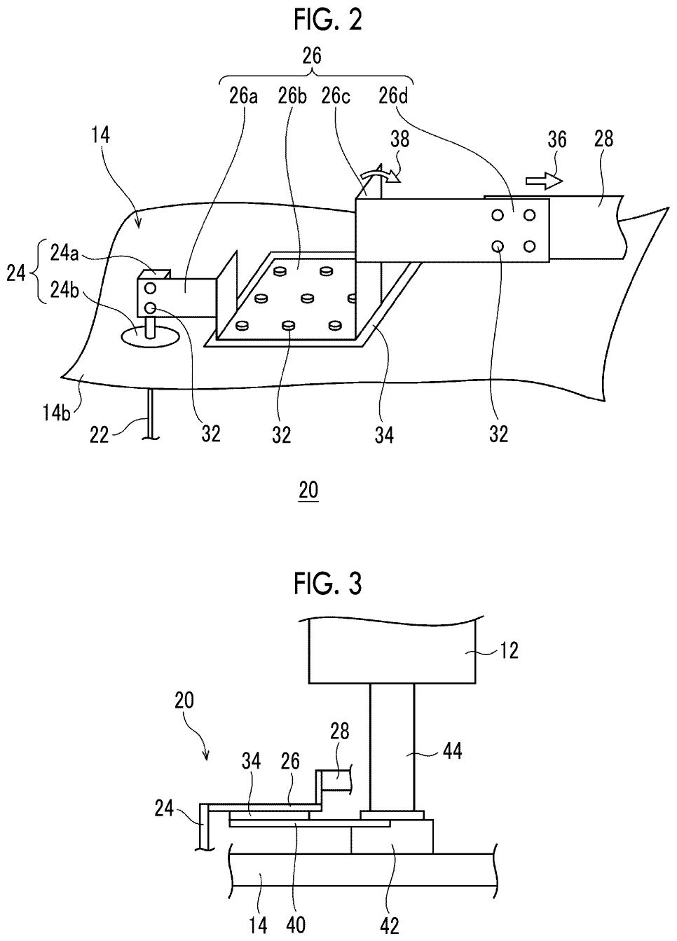

FIG. 2 is a perspective view schematically showing the current introduction line 20 according to the embodiment. As described above, the current introduction line 20 includes the vacuum feedthrough 24, the rigid conductor 26, and the busbar 28 that are electrically connected to each other.

The vacuum feedthrough 24 includes a feedthrough conductor 24a and a feedthrough insulating material 24b. The feedthrough conductor 24a is connected to the external wire 22 at one end exposed to the outside of the vacuum vessel 14, and is connected to the rigid conductor 26 at the other end inside the vacuum vessel 14. In this way, a current path from the external wire 22 to the rigid conductor 26 through the feedthrough conductor 24a is formed.

The feedthrough conductor 24a is inserted through an opening portion of the vacuum vessel 14 (the bottom plate 14b in this example). The opening portion is filled with the feedthrough insulating material 24b to maintain the airtightness of the vacuum vessel 14, and the feedthrough conductor 24a is installed in the vacuum vessel 14 in a state of being electrically insulated from the vacuum vessel 14 by the feedthrough insulating material 24b. The feedthrough insulating material 24b may be, for example, any suitable electrically insulating material such as a synthetic resin material.

The rigid conductor 26 includes a first end portion 26a, a conductor plate 26b, a deformable portion 26c, and a second end portion 26d.

In this embodiment, the rigid conductor 26 is formed of a single plate made of a conductive material (for example, copper) that is bent to form the first end portion 26a, the conductor plate 26b, the deformable portion 26c, and the second end portion 26d. The conductor plate 26b is a flat plate-shaped portion fixed to a fixing surface of the vacuum vessel 14 as will be described later, and has, for example, a rectangular outer shape. The conductor plate 26b may have an outer shape of another shape.

The first end portion 26a extends from a part of an outer periphery of the conductor plate 26b, is bent so as to rise with respect to the fixing surface of the vacuum vessel 14, and is further bent from a rising portion in a direction along the fixing surface of the vacuum vessel 14 toward the feedthrough conductor 24a. Similarly, the second end portion 26d extends from a part of the outer periphery of the conductor plate 26b on a side opposite to the first end portion 26a, is bent to rise with respect to the fixing surface of the vacuum vessel 14, and is further bent from a rising portion in the direction along the fixing surface of the vacuum vessel 14 toward the busbar 28. The rising portion of the second end portion 26d serves as the deformable portion 26c as will be described later.

The first end portion 26a, the conductor plate 26b, the deformable portion 26c, and the second end portion 26d are prepared as individual pieces, and are joined together by an appropriate joining method such as fastening, soldering, or brazing, and may be integrated into the rigid conductor 26.

The rigid conductor 26 is fixed to the vacuum feedthrough 24 at the first end portion 26a, and is fixed to the busbar 28 at the second end portion 26d. The first end portion 26a is fixed to the feedthrough conductor 24a by a fastening member 32 such as a bolt, and the conductor plate 26b is fixed to the busbar 28 by the fastening member 32. The first end portion 26a and the second end portion 26d may be respectively joined to the vacuum feedthrough 24 and the busbar 28 by an appropriate joining method such as soldering or brazing. In this way, a current path from the vacuum feedthrough 24 to the busbar 28 through the rigid conductor 26 is formed.

The conductor plate 26b is fixed to the vacuum vessel 14 so as to sandwich an electrical insulation layer 34 between the vacuum vessel 14 and the conductor plate 26b. The electrical insulation layer 34 may be, for example, a sheet or a plate formed of a synthetic resin material such as glass fiber reinforced plastic (GFRP) or other suitable electrical insulating materials. One surface of the electrical insulation layer 34 is in contact with the fixing surface of the vacuum vessel 14 and the opposite surface of the electrical insulation layer 34 is in contact with a main surface of the conductor plate 26b such that the electrical insulation layer 34 is sandwiched between the vacuum vessel 14 and the conductor plate 26b. Therefore, the conductor plate 26b, that is, the rigid conductor 26 is not in contact with the vacuum vessel 14, and is in a state of being electrically insulated from the vacuum vessel 14. As shown, the conductor plate 26b may be fixed to the vacuum vessel 14 by the fastening member 32 such as a bolt. In this case, in order to prevent electrical conduction between the conductor plate 26b and the vacuum vessel 14 through the fastening member 32 and to ensure electrical insulation between the conductor plate 26b and the vacuum vessel 14, the fastening member 32 may be formed of, for example, a synthetic resin material such as an engineering plastic or other suitable electrically insulating materials. In addition, in a case where a metal fastening member 32 is used, a washer made of an electrically insulating material may be interposed between a head portion of the fastening member 32 and the conductor plate 26b. In this way, the conductor plate 26b, that is, the rigid conductor 26 is fixed to the vacuum vessel 14 in a state of being electrically insulated from the vacuum vessel 14.

Alternatively, the conductor plate 26b may be joined to the electrical insulation layer 34 by any suitable joining method such as bonding. Similarly, the electrical insulation layer 34 may be joined to the vacuum vessel 14 by any suitable joining method.

The conductor plate 26b is thermally coupled to the vacuum vessel 14 via the electrical insulation layer 34. Therefore, heat can flow from the vacuum vessel 14 to the conductor plate 26b through the electrical insulation layer 34. For better thermal connection, it is desirable that a thickness of the electrical insulation layer 34 is as thin as possible. However, in order to ensure the electrical insulation between the conductor plate 26b and the vacuum vessel 14, it is preferable that the electrical insulation layer 34 is relatively thick. Therefore, the thickness of the electrical insulation layer 34 may be selected from, for example, a range of 1 mm to 10 mm. In a case where the electrical insulation layer 34 is a thick plate, input heat from the vacuum vessel 14 to the conductor plate 26b can also be increased by increasing an area of the electrical insulation layer 34 (and the conductor plate 26b) that is in contact with the fixing surface of the vacuum vessel 14.

While the rigid conductor 26 is directly fixed to the vacuum vessel 14 as described above, the busbar 28 is disposed at an interval from the fixing surface of the vacuum vessel 14 to which the rigid conductor 26 is fixed, and is fixed to the vacuum vessel 14 via the rigid conductor 26. The busbar 28 is not in contact with the vacuum vessel 14.

As shown, the busbar 28 may extend along the fixing surface (for example, the bottom plate 14b) of the vacuum vessel 14, or may extend in a lateral direction (horizontal direction) within the vacuum vessel 14 in a case where the vacuum vessel 14 is disposed such that the top plate 14a faces upward and the bottom plate 14b faces downward. In addition, depending on the disposition of internal devices such as the superconducting coil 12 and the heat shield 16 in the vacuum vessel 14, the busbar 28 may extend in another direction, for example, a longitudinal direction (the vertical direction) in the vacuum vessel 14. The busbar 28 may be, for example, a thin plate or a bar having a belt-like or rectangular cross-sectional shape.

As described above, the busbar 28 can be cooled by thermal conduction from the low-temperature section, such as the heat shield 16. Contrary to this, although the conductor plate 26b is connected to the busbar 28, the conductor plate 26b is not cooled as much as the busbar 28 due to input heat from the surrounding environment caused by thermal coupling with the vacuum vessel 14. Since the vacuum vessel 14 has an ambient temperature (for example, room temperature), the conductor plate 26b can be maintained at the ambient temperature or a temperature close to the ambient temperature.

The vacuum feedthrough 24 is exposed to the surrounding environment, and thus, is at the ambient temperature, similar to the vacuum vessel 14. The thermal coupling between the conductor plate 26b and the vacuum vessel 14 can keep the temperature of the conductor plate 26b at the same level as the temperature of the vacuum feedthrough 24, and can reduce a temperature difference between the conductor plate 26 and the vacuum vessel 14 to be smaller than a temperature difference between the low-temperature section such as the heat shield 16 and the rigid conductor 26. The rigid conductor 26 can reduce an influence of the temperature decrease of the busbar 28 due to the thermal conduction from the low-temperature section on the vacuum feedthrough 24.

Therefore, according to the embodiment, by providing the rigid conductor 26 thermally coupled to the vacuum vessel 14 in the current introduction line 20, it is possible to suppress the temperature decrease of the vacuum feedthrough 24 and prevent or reduce the condensation from the surrounding environment onto the vacuum feedthrough 24. Compared to existing countermeasures for condensation using the installation of a heater or the blowing of heated air, it is possible to suppress condensation on the current introduction line 20 of the superconducting magnet device 10 with a simple configuration.

In addition, the rigid conductor 26 is provided with the deformable portion 26c attached to the busbar 28 so that the conductor plate 26b is electrically connected to the busbar 28. As described above, the deformable portion 26c is bent to rise from the conductor plate 26b with respect to the fixing surface of the vacuum vessel 14. Therefore, when the busbar 28 and the second end portion 26d are displaced in an extending direction of the busbar 28 (for example, a left-right direction in the figure), the deformable portion 26c can be bent with respect to the conductor plate 26b.

The low-temperature section such as the heat shield 16 and the busbar 28 can thermally contract by cooling. Accordingly, the busbar 28 can be pulled toward the low-temperature section as schematically shown by an arrow 36 in FIG. 2. In this case, the deformable portion 26c is capable of being bent in response to such deformation of the busbar 28, as schematically shown by an arrow 38. The displacement of the busbar 28 due to thermal contraction is absorbed by the deformable portion 26c. Since the rigid conductor 26 is fixed to the vacuum vessel 14 by the conductor plate 26b, the vacuum feedthrough 24 is less susceptible to an influence of such thermal contraction. It is possible to prevent the occurrence of an excessive thermal stress in, for example, the feedthrough insulating material 24b of the vacuum feedthrough 24, and ultimately the occurrence of unexpected deformation or damage in the vacuum feedthrough 24 and/or the vacuum vessel 14.

The deformable portion 26c is not limited to a bent portion. The deformable portion 26c may have other structures formed in the rigid conductor 26 and deformable in response to the displacement of the busbar 28.

The present invention has been described above based on the embodiment. It will be understood by those skilled in the art that the present invention is not limited to the above embodiments, various design changes can be made, various modification examples are possible, and such modification examples are also within the scope of the present invention. Various features described in relation to a certain embodiment are also applicable to other embodiments. A new embodiment generated through combination also has the effects of each of the combined embodiments.

In the above-described embodiment, a case where the rigid conductor 26 is directly fixed to a wall surface of the vacuum vessel 14 has been described as an example. However, the rigid conductor 26 may be fixed to another part in the vacuum vessel 14 as exemplified below.

FIG. 3 is a side view schematically showing another example of the current introduction line 20 according to the embodiment. As in the above-described embodiment, the current introduction line 20 also includes the vacuum feedthrough 24, the rigid conductor 26, and the busbar 28 in the embodiment of FIG. 3. The rigid conductor 26 electrically connects the vacuum feedthrough 24 to the busbar 28.

However, the rigid conductor 26 is fixed to a support member 40 so as to sandwich the electrical insulation layer 34 between the support member 40 and the rigid conductor 26, and is thermally coupled to the support member 40 via the electrical insulation layer 34. The support member 40 is formed of a metal material such as stainless steel, and may have a plate shape or other shapes. For example, the support member 40 may be fixed to a pedestal 42 fixed to the wall surface of the vacuum vessel 14 in the vacuum vessel 14. A support body 44 that supports the superconducting coil 12 may be attached to the pedestal 42. In this way, the rigid conductor 26 may be thermally coupled to the vacuum vessel 14 via the support member 40.

In addition, in the above-described embodiment, a case where the rigid conductor 26 is a plate member made of a conductive material has been described as an example. However, the rigid conductor 26 is not limited to such a plate, and may be, for example, a rod or a block of conductor.

Although the present invention has been described using specific terms based on the embodiment, the embodiment only shows one aspect of the principle and application of the invention, and the embodiment allows for many modifications and changes in arrangement without departing from the concept of the invention as defined in the claims.

The present invention can be used in the field of a current introduction line and a superconducting magnet device.

It should be understood that the invention is not limited to the above-described embodiment, but may be modified into various forms on the basis of the spirit of the invention. Additionally, the modifications are included in the scope of the invention.

What is claimed is:

1. A current introduction line for introducing a current into a superconducting coil in a vacuum vessel, the current introduction line comprising:
a vacuum feedthrough;
a busbar that is disposed in the vacuum vessel and is electrically connected to the superconducting coil; and
a rigid conductor that is fixed to the vacuum vessel so as to be thermally coupled to the vacuum vessel and to be electrically insulated from the vacuum vessel, and electrically connects the vacuum feedthrough to the busbar.

2. The current introduction line according to claim 1,
wherein the vacuum feedthrough is a hermetically sealed terminal for introducing a current into the vacuum vessel, and connects an external wire to an internal wire inside the vacuum vessel.

3. The current introduction line according to claim 2,
wherein the vacuum feedthrough includes a feedthrough conductor and a feedthrough insulating material, and
the feedthrough conductor is connected to the external wire at one end exposed to an outside of the vacuum vessel, and is connected to the rigid conductor at the other end inside the vacuum vessel.

4. The current introduction line according to claim 3,
wherein the feedthrough conductor is installed in the vacuum vessel in a state of being electrically insulated from the vacuum vessel by the feedthrough insulating material made of an electrically insulating material.

5. The current introduction line according to claim 1,
wherein the rigid conductor includes a conductor plate, and
the conductor plate is fixed to the vacuum vessel so as to sandwich an electrical insulation layer between the vacuum vessel and the conductor plate, and is thermally coupled to the vacuum vessel via the electrical insulation layer.

6. The current introduction line according to claim 1,
wherein the rigid conductor includes a deformable portion that is attached to the busbar so as to electrically connect the rigid conductor to the busbar.

7. The current introduction line according to claim 6,
wherein the deformable portion is bent to rise from a conductor plate of the rigid conductor with respect to a fixing surface of the vacuum vessel.

8. A superconducting magnet device comprising:
a vacuum vessel;
a superconducting coil disposed in the vacuum vessel; and
a current introduction line for introducing a current into the superconducting coil,
wherein the current introduction line includes
a vacuum feedthrough,
a busbar that is disposed in the vacuum vessel and is electrically connected to the superconducting coil, and
a rigid conductor that is fixed to the vacuum vessel so as to be thermally coupled to the vacuum vessel and to be electrically insulated from the vacuum vessel, and electrically connects the vacuum feedthrough to the busbar.
